(19) United States
(12) Patent Application Publication
(10) Pub. No.: US 2017/0277307 A1
(43) Pub. Date: Sep. 28, 2017

(54) TOUCH PANEL AND MANUFACTURING METHOD THEREOF, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Rui Xu, Beijing (CN); Xiaochuan Chen, Beijing (CN); Lei Wang, Beijing (CN); Shengji Yang, Beijing (CN); Yingming Liu, Beijing (CN); Peizhi Cai, Beijing (CN); Haisheng Wang, Beijing (CN)

(21) Appl. No.: 15/511,013

(22) PCT Filed: Apr. 14, 2016
(86) PCT No.: PCT/CN2016/079260

§ 371 Date: Mar. 13, 2017

(30) Foreign Application Priority Data
Jun. 18, 2015 (CN) 201510342254.6

(51) Int. Cl. G06F 3/044; H01L 27/32

(52) U.S. Cl. CPC G06F 3/044; H01L 27/323; G06F 2203/04103

(57) ABSTRACT

A touch panel, a method of manufacturing the touch panel, and a display device are disclosed. The touch panel includes a substrate and a plurality of organic electroluminescence devices disposed on the substrate, each organic electroluminescence device includes a first electrode, a light-emitting layer and a second electrode disposed successively above the substrate, and the touch panel further includes a touch control electrode and a sensing electrode disposed above and insulated from the second electrode.

### CROSS REFERENCE TO RELATED APPLICATIONS

This application is a Section 371 National Stage Application of International Application No. PCT/CN2016/079260, filed on 14 Apr. 2016, entitled “TOUCH PANEL AND MANUFACTURING METHOD THEREOF, AND DISPLAY DEVICE”, which claims priority to Chinese Application No. 201510342254.6, filed on 18 Jun. 2015, incorporated herein by reference in its entirety.

### TECHNICAL FIELD

The present disclosure pertains to the field of display technologies, and particularly, to a touch panel and a manufacturing method thereof, and a display device.

### BACKGROUND

Compared to liquid crystal displays, organic light-emitting diode (OLED) display devices have advantages such as fast respond speed, light weight, flexibility, and wide viewing angle.

An OLED display panel is a main component of an OLED display device. The OLED display panel includes an OLED substrate and an opposite substrate that are aligned and assembled with each other. Presently, display panels having a touch control function are main products in the field of displays. Multi-capacitance full in-cell Touch type OLED display panels have become a focus of research in touch control technologies in recent years due to simple structure and cost efficiency.

### SUMMARY

An object of the present disclosure is to provide a touch panel and a manufacturing method thereof, and a display device, which can improve display quality.

According to an embodiment of the present disclosure, a touch panel is provided, which includes a substrate and a plurality of organic electroluminescence devices disposed on the substrate, where each organic electroluminescence device includes a first electrode, a light-emitting layer and a second electrode disposed successively above the substrate, and the touch panel further comprises a touch control electrode and a sensing electrode disposed above and insulated from the second electrode.

The touch control electrode and the sensing electrode may be arranged in the same layer and formed of the same material.

The touch control electrode may include a plurality of touch control sub-electrodes arranged in a matrix, and the sensing electrode may include a plurality of sensing sub-electrodes arranged in a matrix. The touch control sub-electrodes and the sensing sub-electrodes are arranged alternately in a row direction, and each of the touch control sub-electrodes corresponds to one of the sensing sub-electrodes.

The touch control sub-electrodes located in the same row may be connected together by a metal connecting wire.

Each of the sensing sub-electrodes may include a first sensing sub-electrode and a second sensing sub-electrode. The first sensing sub-electrodes and the second sensing sub-electrodes of the sensing sub-electrodes are alternately arranged in a column direction.

The first sensing sub-electrodes located in the same column may be connected together by a metal connecting wire, and the second sensing sub-electrodes located in the same column may be connected together by another metal connecting wire.

The touch control sub-electrodes may each have a rectangular shape, a diamond shape or a square shape.

The first sensing sub-electrode and the second sensing sub-electrode may each have a rectangular shape, a diamond shape or a square shape.

The touch panel may further include a first insulation layer and a second insulation layer, the sensing electrode is arranged above the second electrode and insulated from the second electrode by the first insulation layer, and the touch control electrode is arranged above the sensing electrode and insulated from the sensing electrode by the second insulation layer.

The first electrode may be an anode and the second electrode may be a cathode.

Alternatively, the first electrode may be a cathode and the second electrode may be an anode.

The plurality of organic electroluminescence devices may include a red organic electroluminescence device, a green organic electroluminescence device and a blue organic electroluminescence device.

The plurality of organic electroluminescence devices may be an organic electroluminescence device configured for emitting white light.

According to another embodiment of the present disclosure, there is provided a method of manufacturing the above touch panel. The method include: forming patterns including the first electrode, the light-emitting layer and the second electrode of the organic electroluminescence device successively on the substrate through patterning processes; forming a first insulation layer on the second electrode; and forming a pattern including the touch control electrode and the sensing electrode on the first insulation layer.

In the method, the touch control electrode and the sensing electrode may be formed through a single patterning process.

Alternatively, the step of forming the pattern including the touch control electrode and the sensing electrode includes: forming a pattern including the sensing electrode on the first insulation layer through a patterning process; forming a second insulation layer on the pattern including the sensing electrode; and forming a pattern including the touch control electrode on the second insulation layer through a patterning process.

According to another embodiment of the present disclosure, there is provided a display device, which includes the above described touch panel.

In the touch panel according to the embodiments of the disclosure, the touch control electrode and the sensing electrode are disposed on the second electrode of the organic electroluminescence device and insulated from the second electrode. In other words, each of the touch control electrode and the sensing electrode is disposed in a different layer from the layer in which the second electrode lies, so that the second electrode can be protected from being influenced by an electric field formed between the touch control electrode and the sensing electrode. Therefore, as compared with existing touch panels, the touch panel according to the embodiments of the disclosure may ensure that the organic electroluminescence device can emit light normally. Additionally, the touch panel in the embodiments of the disclosure is a multi-capacitance full in-cell touch panel, which has a simple structure, low cost and strong applicability.

### BRIEF DESCRIPTION OF THE DRAWINGS

FIG. 1 is a cross-sectional view showing an OLED substrate in a touch panel according to an embodiment of the disclosure.

FIG. 2 is a plan view showing an OLED substrate in a touch panel according to an embodiment of the disclosure.

FIG. 3 is a cross-sectional view showing an OLED substrate in a touch panel according to an embodiment of the disclosure.

FIG. 4 is a flow chart showing a method of manufacturing a touch panel according to an embodiment of the disclosure.

FIG. 5 is a flow chart showing a method of manufacturing a touch panel according to an embodiment of the disclosure.

### DETAILED DESCRIPTION OF PREFERRED EMBODIMENTS

Exemplary embodiments of the present disclosure will be described hereinafter in detail with reference to the attached drawings, such that those skilled in the art could fully understand technical solutions of the disclosure.

A touch control electrode and a sensing electrode of a multi-capacitance full in-cell touch type OLED display panel are disposed at light exit surface of an OLED substrate, and in normal situations, the sensing electrode and a cathode of an OLED device on the OLED substrate are formed through a single patterning process (the sensing electrode and the cathode are formed in the same layer and from the same material), such that an electric field formed between the touch control electrode and the sensing electrode can easily influence the cathode, resulting in abnormal light emitting of the OLED, and in turn, the OLED display panel cannot display normally.

The present disclosure is provided to solve the above technical problem.

An embodiment of the disclosure provides a touch panel including an OLED substrate and an opposite substrate that are aligned and assembled. Specifically, the OLED substrate includes a substrate 10 and a plurality of organic electroluminescence devices disposed on the substrate 10, as shown in FIGS. 1-3. Each organic electroluminescence device includes a first electrode 3, a light-emitting layer 5 and a second electrode 6 disposed successively above the substrate 10. The touch panel further includes a touch control electrode and a sensing electrode disposed above the second electrode 6 and insulated from the second electrode 6.

In the touch panel according to the embodiment of the disclosure, the touch control electrode and the sensing electrode are disposed on the second electrode 6 of the organic electroluminescence device and insulated from the second electrode 6. In other words, each of the touch control electrode and the sensing electrode is disposed in a different layer from the layer in which the second electrode 6 lies, so that the second electrode 6 can be protected from being influenced by an electric field formed between the touch control electrode and the sensing electrode. Therefore, as compared with existing touch panels, the touch panel according to the embodiment of the disclosure may ensure that the organic electroluminescence device can emit light normally. Additionally, the touch panel in this embodiment of the disclosure is a multi-capacitance full in-cell touch panel, which has a simple structure, low cost and strong applicability.

In an embodiment of the disclosure, the touch control electrode and the sensing electrode of the touch panel are arranged in the same layer and formed of the same material. Therefore, the touch control electrode and the sensing electrode can be formed through a single patterning process, such that cost may be reduced and production capability may be improved. Further, arranging the touch control electrode and the sensing electrode in the same layer may also facilitate thinning and reducing weight of the display panel.

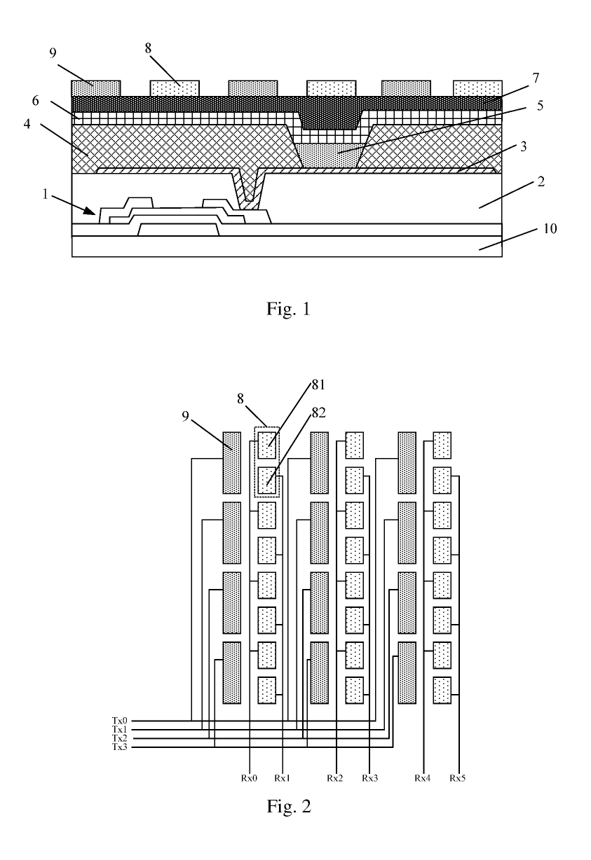

As shown in FIGS. 1 and 2, specifically, the touch control electrode includes a plurality of touch control sub-electrodes 9 arranged into a matrix, and the sensing electrode includes a plurality of sensing sub-electrodes 8 arranged into a matrix. The touch control sub-electrodes 9 and the sensing sub-electrodes 8 are arranged alternately in a row direction, and each of the touch control sub-electrodes 9 corresponds to one of the sensing sub-electrodes 8. It is noted that, the definition of “each of the touch control sub-electrodes 9 corresponds to one of the sensing sub-electrodes 8” means that each touch control sub-electrode 9 is arranged adjacent to a corresponding sensing sub-electrodes 8 in the row direction, as shown in FIG. 2.

In some embodiments, touch control sub-electrodes 9 located in the same row are connected together by a metal connecting wire. That is to say, when a touch control scanning signal is input to the touch control sub-electrodes 9, the touch control sub-electrodes are scanned row by row, thus, there is no need to input a touch control scanning signal to each touch control sub-electrode 9 separately, such that the number of metal connecting wires can be reduced, wiring may be facilitated, timing sequence may be simplified, and the aperture opening ratio of the touch panel may be increased.

In some embodiments, each sensing sub-electrode 8 includes a first sensing sub-electrode 81 and a second sensing sub-electrode 82. In a column direction, first sensing sub-electrodes 81 and second sensing sub-electrodes 82 are alternately arranged, the first sensing sub-electrodes 81 located in the same column are connected together by a metal connecting wire, and the second sensing sub-electrodes 82 located in the same column are connected together by a metal connecting wire. This type of connection is similar to that of the connection of the touch control sub-electrodes 9, both of which are to reduce the number of metal connecting wires, facilitate wiring, simplify timing sequence, and increase the aperture opening ratio of the touch panel.

It is to be noted that the structure of each sensing sub-electrode 8 is not limited to the structure set forth above. In another embodiment, each sensing sub-electrode 8 may include the first sensing sub-electrode, the second sensing sub-electrode and a third sensing sub-electrode. In still another embodiment, each sensing sub-electrode 8 may include a plurality of small sensing sub-electrodes. In a further embodiment, each sensing sub-electrode 8 may include a one-piece structure.

In some embodiments, shapes of the touch control sub-electrode 9, the first sensing sub-electrode 81 and the second sensing sub-electrode 82 may be any one of rectangular, diamond and square. In other embodiments, the touch control sub-electrode 9, the first sensing sub-electrode 81 and the second sensing sub-electrode 82 may also have other shapes.

In the embodiments shown in FIGS. 1 and 2, the touch control electrode and the sensing electrode are arranged in the same layer, and a position of touch control may be determined by a fringing field formed at edges of the touch control electrode and the sensing electrode. The principle of determining the position of touch in this manner is known to those skilled in the art and will not be described in detail herein.

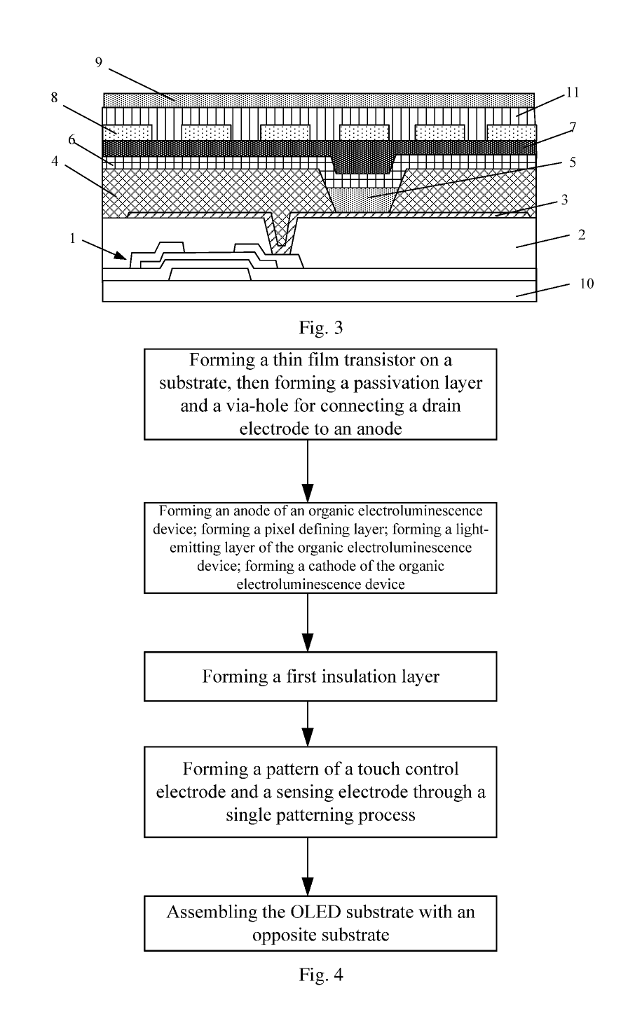

In an embodiment of the disclosure, as shown in FIG. 3, the sensing electrode of the touch panel is arranged above the second electrode 6 and insulated from the second electrode 6 by a first insulation layer 7. Additionally, the touch control electrode of the touch panel is arranged above the sensing electrode and insulated from the sensing electrode by a second insulation layer 11.

In other words, the touch control electrode and the sensing electrode may also be arranged in different layers. The sensing electrode may include a plurality of strip-shaped sensing sub-electrodes 8 disposed in parallel with each other, and the touch control electrode may include a plurality of strip-shaped touch control sub-electrodes 9 disposed in parallel with each other. The touch control sub-electrodes 9 and the sensing sub-electrodes 8 are arranged to cross and be insulated from each other, and each crossing position thereof may represent a touch control point, thus, a position of a touch control point may be determined by a change in capacitance at the crossing position between the touch control sub-electrode 9 and the sensing sub-electrode 8.

In some embodiments, the first electrode 3 is an anode, and the second electrode 6 is a cathode. In other embodiments, the first electrode 3 is a cathode, while the second electrode 6 is an anode.

In an embodiment of the disclosure, a material of the anode may be a transparent electrode material, such as indium tin oxide (ITO), indium gallium tin oxide (IGTO) or the like, a material of the cathode may be an non-transparent electrode material, such as Copper (Cu), Aluminum (Al), Silver (Ag) or the like.

In an embodiment of the disclosure, the plurality of organic electroluminescence devices may include three organic electroluminescence devices of different colors, including a red organic electroluminescence device, a green organic electroluminescence device and a blue organic electroluminescence device. The plurality of organic electroluminescence devices are arranged periodically in color. Three organic electroluminescence devices including one red organic electroluminescence device, one green organic electroluminescence device and one blue organic electroluminescence device form one pixel unit, so as to obtain a full-color pixel unit of the touch panel. In this case, no color filter layer is needed to be formed on the opposite substrate, such that manufacturing process of the touch panel may be simplified, and thickness of the touch panel is relative smaller.

In an embodiment of the disclosure, the plurality of organic electroluminescence devices may also be organic electroluminescence devices emitting white light. In this case, the opposite substrate is a color filter substrate, so as to achieve full-color pixel units of the touch panel.

An embodiment of the disclosure further provides a method of manufacturing a touch panel, and the method is used to manufacture the touch panel according to the embodiment shown in FIG. 1. In this embodiment, the method is described by an example where the first electrode 3 is an anode and the second electrode 6 is a cathode. As shown in FIG. 4, the method includes the following steps S1 to S5.

Step S1 includes: forming various layer structures including a thin film transistor 1 on the substrate 10, then forming a passivation layer 2 and etching the passivation layer 2 to form a via configured for connecting a drain electrode of the thin film transistor 1 with the anode of the organic electroluminescence device.

Step S2 includes: after the above step, forming a pattern including the anode of the organic electroluminescence device on the substrate 10 through a patterning process; then forming a pixel defining layer 4 and forming a light-emitting material in the pixel defining layer 4 to form the light-emitting layer 5 of the organic electroluminescence device; and then, forming a pattern of the cathode of the organic electroluminescence device.

Step S3 includes: after the above steps, forming the first insulation layer 7 on the substrate 10.

Step S4 includes: after the above steps, forming a pattern including the touch control electrode 9 and the sensing electrode 8 on the substrate 10 through a single patterning process.

In this step, the touch control electrode 9 and the sensing electrode 8 are formed through a single patterning process. In other words, the touch control electrode 9 and the sensing electrode 8 are arranged in the same layer and have the same material. In this case, processing steps may be simplified and production cost may be reduced. Production of the OLED substrate is achieved though the above steps S1 to S4.

In some embodiments, the touch control electrode 9 and the sensing electrode 8 may include a transparent and conductive material, such as ITO (Indium Tin Oxide), IZO (Indium Zinc Oxide), IGZO (Indium Gallium Zinc Oxide) or IGTO (Indium Gallium Tin Oxide).

Step S5 includes: Assembling the OLED substrate with the opposite substrate to form the touch panel.

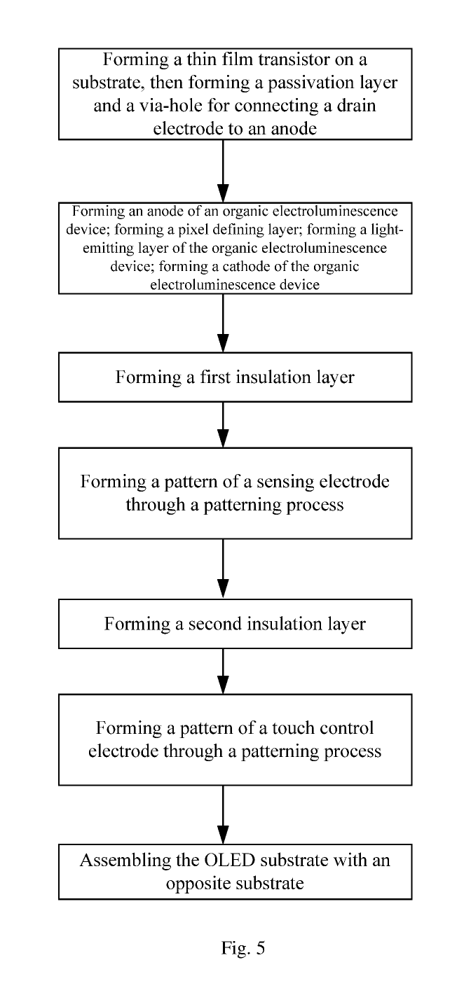

An embodiment of the disclosure further provides a method of manufacturing a touch panel, and the method is used to manufacture the touch panel according to the embodiment shown in FIG. 3. In this embodiment, the method is described by an example where the first electrode 3 is an anode and the second electrode 6 is a cathode. As shown in FIG. 5, the method includes the following steps S1 to S7.

Step S1 includes: forming various layer structures including a thin film transistor 1 on the substrate 10, then forming a passivation layer 2 and etching the passivation layer 2 to form a via configured for connecting a drain electrode of the thin film transistor 1 with the anode of the organic electroluminescence device.

Step S2 includes: after the above step, forming a pattern including the anode of the organic electroluminescence device on the substrate 10 through a patterning process; then forming a pixel defining layer 4 and forming a light-emitting material in the pixel defining layer 4 to form the light-emitting layer 5 of the organic electroluminescence device; and then, forming a pattern of the cathode of the organic electroluminescence device.

Step S3 includes: after the above steps, forming the first insulation layer 7 on the substrate 10.

Step S4 includes: after the above steps, forming a pattern of the touch control electrode 9 on the substrate 10 through a patterning process.

Step S5 includes: after the above steps, forming the second insulation layer 11 on the substrate 10.

Step S6 includes: after the above steps, forming a pattern of the touch control electrode 8 on the substrate 10 through a patterning process.

In some embodiments, the touch control electrode 9 and the sensing electrode 8 may include a transparent and conductive material, such as ITO (Indium Tin Oxide), IZO (Indium Zinc Oxide), IGZO (Indium Gallium Zinc Oxide) or IGTO (Indium Gallium Tin Oxide). Production of the OLED substrate is achieved though the above steps S1 to S6.

Step S7 includes: assembling the OLED substrate with the opposite substrate to form the touch panel.

An embodiment of the disclosure further provides a display device, which includes the above described touch panel. The display device provided in this embodiment has a smaller thickness and a better performance.

The display device may be any product or part having a display function, such as a mobile phone, a tablet computer, a TV set, a display, a notebook computer, a digital photo frame, a navigator or the like.

Additionally, the display device according to this embodiment may further include other customary structures, such as a power source unit, a display driving unit and the like.

It would be understood that the above embodiments are merely described to exemplarily illustrate principles of the present disclosure. However, the present disclosure is not limited thereto. It would be appreciated by those skilled in the art that various changes or modifications may be made to these embodiments without departing from the principles and spirit of the disclosure, and these changes or modifications shall also fall within the scope of this disclosure.

1. A touch panel, comprising a substrate and a plurality of organic electroluminescence devices disposed on the substrate, wherein
each organic electroluminescence device includes a first electrode, a light-emitting layer and a second electrode disposed successively above the substrate; and
the touch panel further comprises a touch control electrode and a sensing electrode disposed above and insulated from the second electrode.

2. The touch panel according to claim 1, wherein the touch control electrode and the sensing electrode are arranged in the same layer and formed of the same material.

3. The touch panel according to claim 2, wherein the touch control electrode comprises a plurality of touch control sub-electrodes arranged in a matrix, and the sensing electrode comprises a plurality of sensing sub-electrodes arranged in a matrix; and wherein each of the touch control sub-electrodes corresponds to one of the sensing sub-electrodes arranged spaced apart from the touch control sub-electrode in a row direction.

4. The touch panel according to claim 3, wherein the touch control sub-electrodes located in the same row are connected together by a metal connecting wire.

5. The touch panel according to claim 3, wherein each of the sensing sub-electrodes comprises a first sensing sub-electrode and a second sensing sub-electrode,
and wherein the first sensing sub-electrodes and the second sensing sub-electrodes of the sensing sub-electrodes are alternately arranged in a column direction.

6. The touch panel according to claim 5, wherein the first sensing sub-electrodes located in the same column are connected together by a metal connecting wire and the second sensing sub-electrodes located in the same column are connected together by another metal connecting wire.

7. The touch panel according to claim 3, wherein the touch control sub-electrodes each have a rectangular shape, a diamond shape or a square shape.

8. The touch panel according to claim 5, wherein the first sensing sub-electrode and the second sensing sub-electrode each have a rectangular shape, a diamond shape or a square shape.

9. The touch panel according to claim 1, further comprising a first insulation layer and a second insulation layer, wherein
the sensing electrode is arranged above the second electrode and insulated from the second electrode by the first insulation layer; and
the touch control electrode is arranged above the sensing electrode and insulated from the sensing electrode by the second insulation layer.

10. The touch panel according to claim 1, wherein the first electrode is an anode and the second electrode is a cathode.

11. The touch panel according to claim 1, wherein the first electrode is a cathode and the second electrode is an anode.

12. The touch panel according to claim 1, wherein the plurality of organic electroluminescence devices comprise a red organic electroluminescence device, a green organic electroluminescence device and a blue organic electroluminescence device.

13. The touch panel according to claim 1, wherein the plurality of organic electroluminescence devices comprises an organic electroluminescence device configured for emitting white light.

14. A method of manufacturing the touch panel according to claim 1, comprising:
forming patterns including the first electrode, the light-emitting layer and the second electrode of the organic electroluminescence device successively on the substrate through patterning processes;
forming a first insulation layer on the second electrode; and
forming a pattern including the touch control electrode and the sensing electrode on the first insulation layer.

15. The method according to claim 14, wherein the touch control electrode and the sensing electrode are formed through a single patterning process.

16. The method according to claim 14, wherein forming the pattern including the touch control electrode and the sensing electrode comprises:
forming a pattern including the sensing electrode on the first insulation layer through a patterning process;
forming a second insulation layer on the pattern including the sensing electrode; and
forming a pattern including the touch control electrode on the second insulation layer through a patterning process.

17. A display device, comprising the touch panel according to claim 1.
